(19) United States
(12) Patent Application Publication
(10) Pub. No.: US 2003/0082920 A1
(43) Pub. Date: May 1, 2003

(54) Chamber-reversed dry etching

(75) Inventors: Yuan-sheng Huang, Hualien City (TW); Hsin-Yi Chen, Vancouver, WA (US)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/004,614

(22) Filed: Nov. 1, 2001

(51) Int. Cl. H01L 21/302; H01L 21/461

(52) U.S. Cl. 438/710

(57) ABSTRACT

Chamber-reversed dry etching is disclosed. A semiconductor dry etching system can include a plasma chamber, a wafer lifter, a wafer chuck, and a bias supply. Polymer is introduced into the plasma chamber, such that excess polymer forms and subsequently peels off the inner vertical walls of the chamber, and falls down due to gravity. The wafer lifter holds the semiconductor wafer upside-down over the plasma chamber, preventing the excess polymer from falling onto the wafer. The wafer chuck moves the wafer upside-down to over the plasma chamber for the wafer lifter to hold the wafer upside-down over the plasma chamber. The bias supply biases the wafer, such that the polymer is electro-statically attracted to the wafer.

### FIELD OF THE INVENTION

This invention relates generally to semiconductor processing, and more particularly to the dry etching semiconductor process.

### BACKGROUND OF THE INVENTION

There are four basic operations in semiconductor processing, layering, patterning, doping, and heat treatments. Layering is the operation used to add thin layers to the surface of a semiconductor wafer. Patterning is the series of steps that results in the removal of selected portions of the layers added in layering. Doping is the process that puts specific amounts of dopants in the wafer surface through openings in the surface layers. Finally, heat treatments are the operations in which the wafer is heated and cooled to achieve specific results, where no additional material is added or removed from the wafer.

Of these four basic operations, patterning is typically the most critical. The patterning operation creates the surface parts of the devices that make up a circuit on the semiconductor wafer. The operation sets the critical dimensions of these devices. Errors during patterning can cause distorted or misplaced defects that result in changes in the electrical function of the device, as well as device defects.

The patterning process is also known by the terms photomasking, masking, photolithography, and microlithography. The process is a multi-step process similar to photography or stenciling. The required pattern is first formed in photomasks and transferred into the surface layers of the semiconductor wafer. This is shown by reference to FIGS. 1A and 1B. In FIG. 1A, the wafer 100 has an oxide layer 102 and a photoresist layer 104. The wafer 100 itself may be referred to as the silicon or semiconductor substrate. The oxide layer 102 is a dielectric, which is a material that conducts no current when it has a voltage across it. Oxide, or more specifically silicon dioxide, is one type of dielectric, whereas another type is silicon nitride.

A mask 106 is precisely aligned over the wafer 100, and the photoresist 104 is exposed, as indicated by the arrows 108. This causes the exposure of the photoresist layer 104, except for the part 110 that was masked by the part 112 of the mask 106. In FIG. 1B, the unexposed part 110 of the photoresist layer 104 is removed, creating a hole 114 in the photoresist layer 104.

Next, a second transfer takes place from the photoresist layer 104 into the oxide layer 102. This is shown in FIG. 1C, where the hole 114 extends through both the photoresist layer 104 and the oxide layer 102. The transfer occurs when etchants remove the portion of the wafer's top layer that is not covered by photoresist. The chemistry of photoresists is such that they do not dissolve, or dissolve very slowly, in the chemical etching solutions. Finally, the photoresist layer 104 is removed, as shown in FIG. 1D, such that only the wafer 100 and the oxide layer 102 with the hole 114 remains.

The removal of the photoresist layer can be accomplished by either wet or dry etching. Wet etching refers to the use of wet chemical processing to remove the photoresist. The chemicals are placed on the surface of the wafer, or the wafer itself is submerged in the chemicals. Dry etching refers to the use of plasma stripping, using a gas such as oxygen (O₂), C₂F₆ and O₂, or another gas. Whereas wet etching is a low-temperature process, dry etching is typically a high-temperature process.

In one type of dry etching process, the wafer is placed within a chamber and is exposed to plasma. The plasma has its temperature modified by being subjected to electromagnetic fields. Precise control of the fields allows for proper stripping, or etching, of the dielectric from the semiconductor wafer. More specifically, plasma etching is performed by applying electrical and/or magnetic fields to a gas containing some chemically reactive element, like fluorine or chlorine. The plasma releases chemically reactive ions that can remove, or etch, materials very rapidly. It also gives the chemicals an electrical charge that directs them toward the wafer vertically. For such plasma-assisted dry etching, polymer formation is typically utilized for etched film sidewall passivation purposes, to ensure proper vertical profiling of the at least partially fabricated devices on the wafer during the dry etch process.

FIG. 2 shows an example of a dry etch system 200. The system 200 includes a plasma chamber 202 surrounded by multi-pole magnets 204 and 206, as well as an induction coil 210 separated from the chamber 202 via a window 208. The magnets 204 and 206, in conjunction with the induction coil 210, produce varying magnetic fields within the chamber 202, providing for proper dry etching of the wafer 220 placed inside the chamber 202, as moved thereto via a wafer chuck 218. The induction coil 210 is connected to both ground 212 and an inductive supply 214, where the supply 214 is itself also connected to ground 216. The inductive supply 214 ensures that the induction coil 210 generates varying magnetic fields. The wafer chuck 218, and hence the wafer 220, are biased through a bias supply 222 connected to ground 224. Polymer introduced into the chamber 202 is electrostatically attracted to the wafer 220 because of the biasing of the wafer chuck 218 through the bias supply 222. The bias supply 222 thus acts as a cathode.

A disadvantage to the system 200, however, is that inevitably polymer also forms on the inner surfaces of the etch chamber 202 in addition to the wafer 220. However, the polymer layers formed on these inner surfaces have poor adhesion, as a result of temperature variation of the surfaces caused by the system 200 being turned on and off, turbulence due to plasma gas flow and pumping thereof into and out of the chamber 202, as well other factors. Such poor adhesion means that the polymer frequently peels away off the inside surfaces of the etch chamber 202, falling downward due to gravity onto the wafer 220. These polymer particles are generally quite large, of heavy mass, and usually electrically neutral or only lowly charged. Their falling onto the wafer 220 causes defects in the semiconductor devices being fabricated on the wafer 220, decreasing yield and thus increasing cost to the semiconductor manufacturer.

Therefore, there is a need for a plasma dry etch system in which polymer can be introduced, but that does not cause the problems associated with the prior art. More specifically, there is a need for such a dry etch system in which polymer particles do not peel off from the inner surfaces of the plasma chamber and onto the semiconductor wafer. Such a dry etch system should increase yield by preventing device defects on the devices being fabricated on the wafer. For these and other reasons, there is a need for the present invention.

### SUMMARY OF THE INVENTION

The invention relates to chamber-reversed dry etching. A semiconductor dry etching system of the invention can include at least a plasma chamber, a wafer lifter, and a bias supply. Polymer is introduced into the plasma chamber, such that excess polymer forms and subsequently peels off the inner vertical walls of the chamber, and falls down due to gravity. The wafer lifter holds the semiconductor wafer upside-down over the plasma chamber, preventing the excess polymer from falling onto the wafer. The bias supply biases the wafer, such that the polymer is electrostatically attracted to the wafer.

The invention provides for advantages over the prior art. By positioning the semiconductor wafer over the plasma chamber, instead of below the plasma chamber as in the prior art, excess polymer that forms on the walls of the chamber and subsequently falls off does not land on the wafer. Semiconductor device yield thus improves, decreasing cost to the semiconductor manufacturer. Proper polymerization of the wafer is still ensured by the electrostatic coupling of the polymer to the wafer. Other advantages, embodiments, and aspects of the invention will become apparent by reading the detailed description that follows, and by referencing the attached drawings.

### BRIEF DESCRIPTION OF THE DRAWINGS

FIGS. 1A, 1B, 1C, and 1D are diagrams illustrating the al patterning process performed in semiconductor manufacture.

FIG. 2 is a diagram showing an example dry etch system having a plasma chamber.

FIG. 3 is a diagram showing a dry etch system including a wafer lifter and/or other electrically biased mechanism, according to an embodiment of the invention.

FIGS. 4A and 4B are diagrams showing a cross-sectional lateral view and a perspective tilted view, respectively, of the wafer lifter of FIG. 3, according to an embodiment of the invention.

FIG. 5 is a flowchart of a method according to an embodiment of the invention that can be used in conjunction with the dry etch system of FIG. 3.

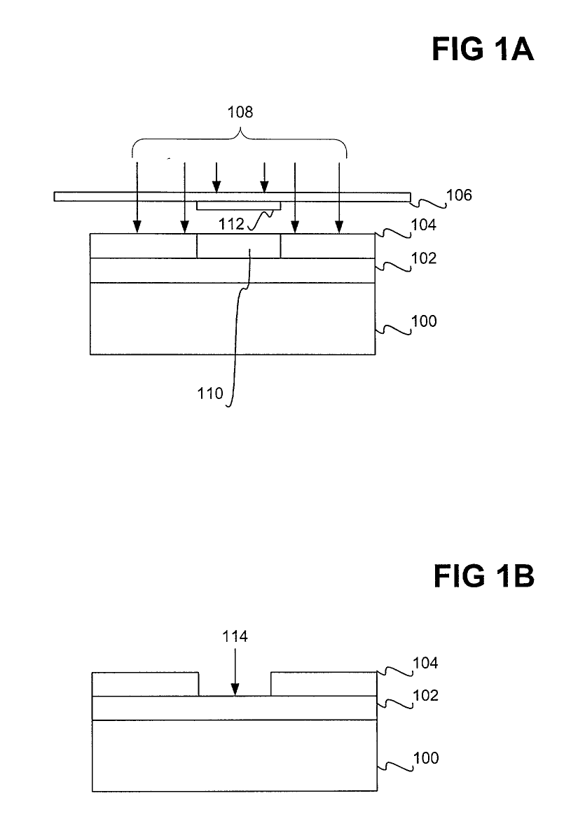

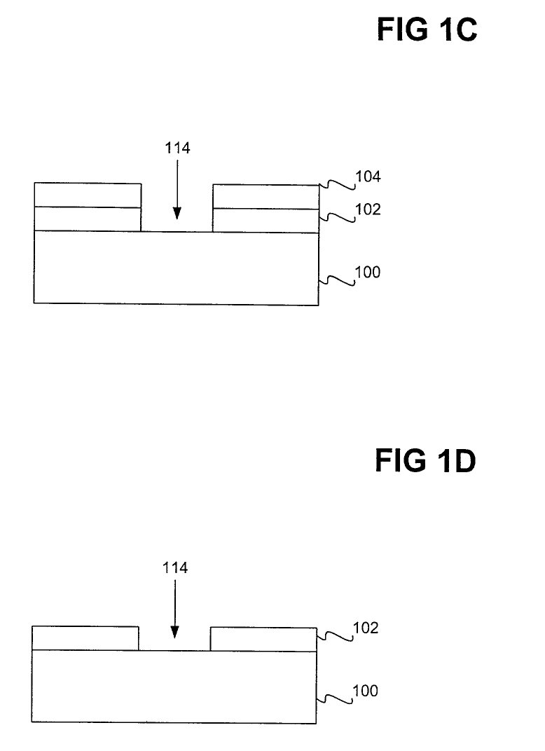

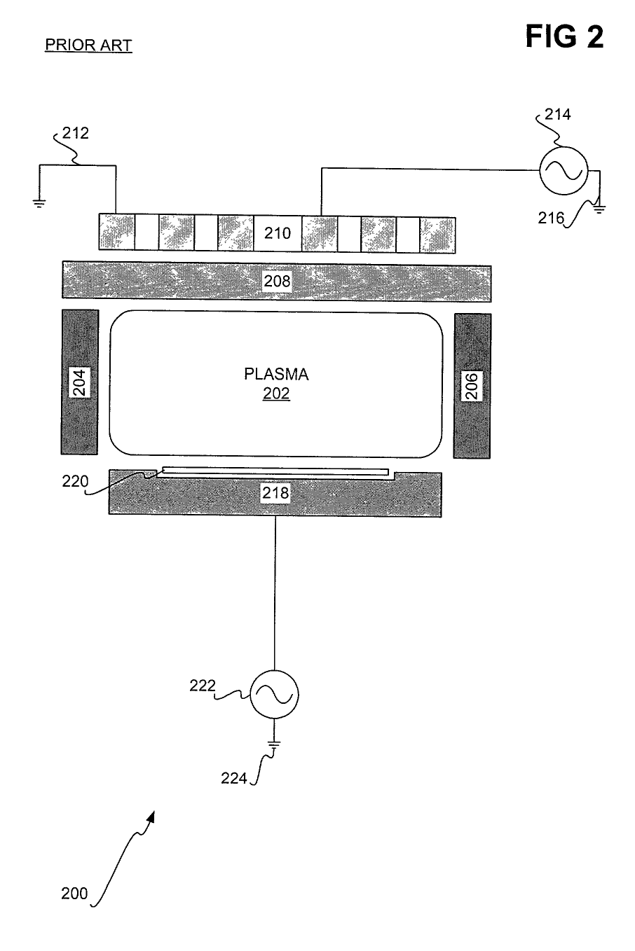

### DETAILED DESCRIPTION OF THE INVENTION

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

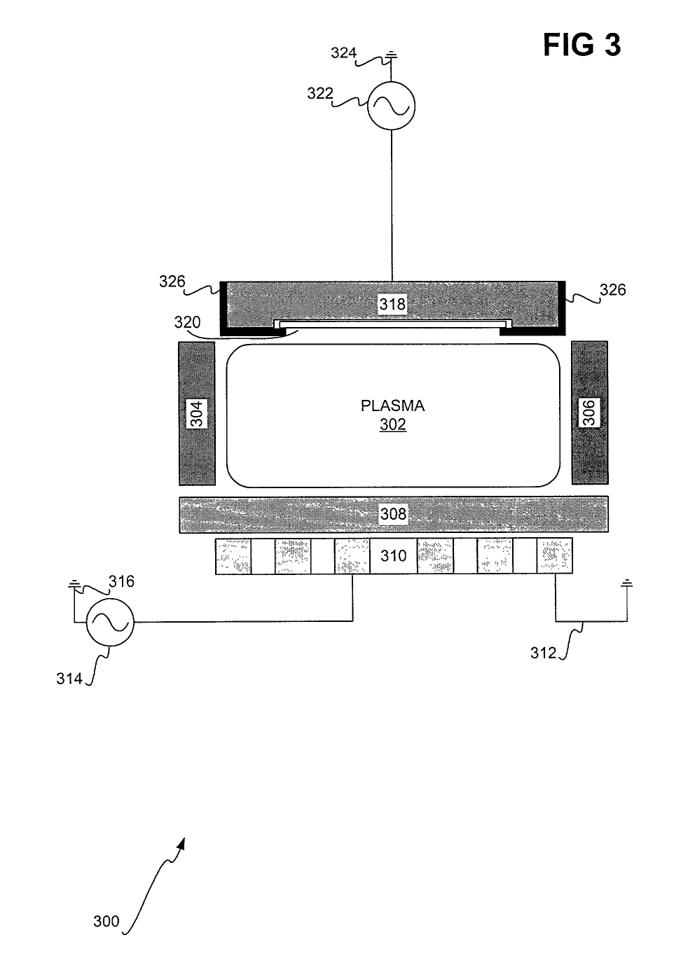

FIG. 3 shows a dry etch system 300 according to an embodiment of the invention. The system 300 includes a plasma chamber 302 surrounded by multi-pole magnets 304 and 306, as well as an induction coil 310 separated from the chamber 302 via a window 308, such as a dielectric window. The magnets 304 and 306, in conjunction with and in cooperation of the induction coil 310, produce varying magnetic fields within the chamber 302. This provides for proper dry etching of the wafer 320 placed inside the chamber 302. There may be one or more induction coils besides the coil 310. Furthermore, the coils may be electromagnetic coils in lieu of being induction coils. The induction coil 310 is connected to both ground 312 and an inductive supply 314, where the supply 314 itself is also connected to ground 316. Where the coil 310 is an electromagnetic coil, the supply 314 is an electromagnetic supply. The supply 314 ensures that the coil 210 generates varying magnetic fields.

The wafer 320 is moved upside-down via the wafer chuck 318 into the wafer lifter 326, which holds the wafer 320 in an upside-down position during dry etching. The wafer lifter 326 has a lower position and an upper position. In the lower position, the chuck 318 is able to move over the plasma chamber 302 such that the lifter 326 can receive or load the wafer 320 from the chuck 318. The lower position thus promotes loading of the wafer 320. It is noted that at least one or more of the wafer lifter 326, the bias supply 322, and the wafer chuck 318 can act as an electrically biased mechanism to hold the wafer 320 over the chamber 302.

In the upper position, which is specifically shown in FIG. 3, the wafer chuck 318 touches the bias supply 322, which is itself connected to ground 324. The upper position thus enables the bias supply 322 to electrically couple with the wafer chuck 322, and hence the wafer 320, for biasing of the wafer 320. More specifically, connection of the chuck 318 to the supply 322 electrically couples the supply 322 to the wafer 320, such that the wafer 320 is electrically charged. Such electric charging of the wafer 320, resulting from the biasing of the chuck 318, ensures that polymer introduced into the chamber 302 is electrostatically attracted to the wafer 320. The bias supply 322 thus acts as a cathode.

Inevitable polymer formation on the inner surfaces of the etch chamber 302 that subsequently peels off and falls down due to gravity does not land onto the wafer 320. This is because the wafer 320 is positioned over the plasma chamber 302, and not under the plasma chamber 302 as in the prior art. That is, positioning of the wafer 320 over the chamber 302 prevents the excess polymer from landing onto the wafer 320. Thus, large and heavy polymer particles, which are not attracted to the wafer 320 because of their electrically neutral or lowly charged nature, fall harmlessly onto the dielectric window 308. This prevents defects from occurring on the semiconductor devices being fabricated on the wafer 320, increasing yield and decreasing cost to the semiconductor manufacturer.

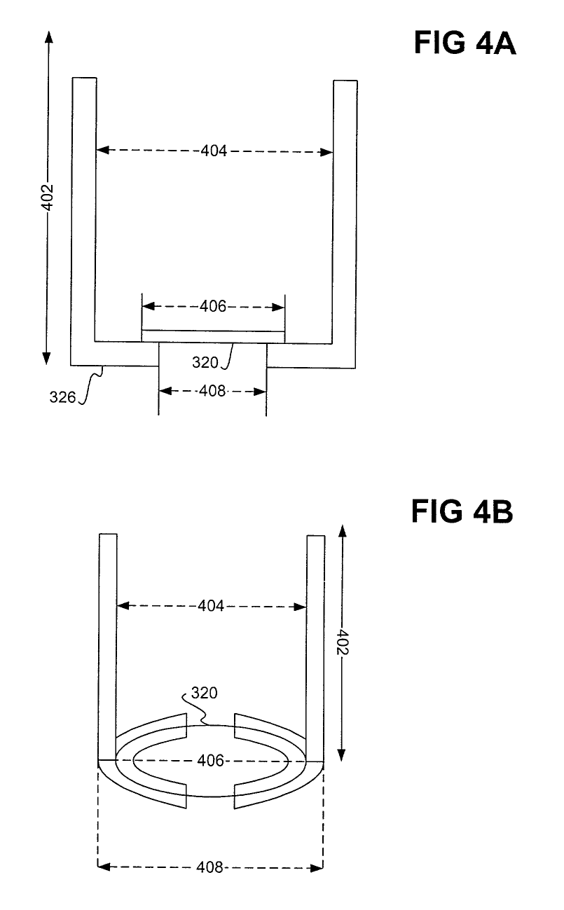

FIGS. 4A and 4B show the wafer lifter 326 in more detail. FIG. 4A is a cross-sectional lateral view of the wafer lifter 326, whereas FIG. 4B is a perspective tiled view of the wafer lifter 326. As indicated by the dual-arrowed line 402, the wafer lifter is movable vertically, between an upper position and a lower position as has been described. As specifically shown in FIG. 4B, the wafer lifter has a tubular bodying having a substantially open-ended cap at a downward-facing end thereof, against which the semiconductor wafer 320 is held upside-down, such that the face of the wafer 320 is oriented downward. The tubular body of the wafer lifter 326 has an inner diameter 404. The open-ended cap has a diameter 408 that is less than the inner diameter 404. The wafer 320 has a diameter 406 that is less than the inner diameter 404, but greater than the diameter 408. Because the diameter 404 is greater than the diameter 406 which is greater than the diameter 408, the wafer 320 is able to fit inside the lifter 326, but not fall through the end of the lifter 326.

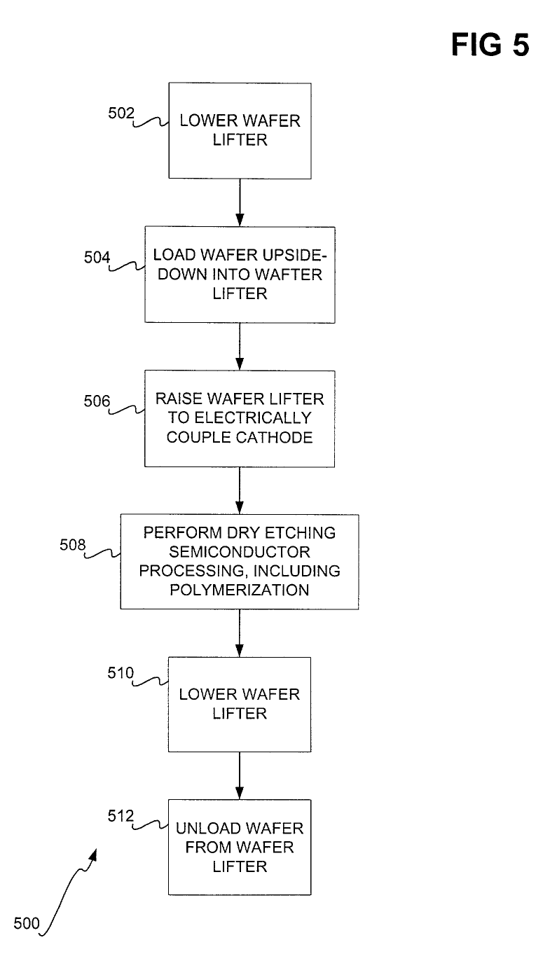

FIG. 5 shows a method 500 according to an embodiment of the invention that can be used in conjunction with the dry etch system 300 of FIG. 3 that has been described. First, the wafer lifter is lowered to its lowered position (502), so that a semiconductor wafer can be loaded upside-down into the wafer lifter (504) . Loading can be accomplished by chucking of the wafer in an upside-down, face-downward position through use of a wafer chuck. The wafer lifter is then raised to its raised position to electrically couple the wafer with a cathode (506). The cathode may be a bias supply, for instance, where the wafer is electrically coupled therewith via the wafer chuck making contact with the bias supply.

Dry etching semiconductor processing is then performed, which may include polymerization of the wafer (508). During processing, the lifter can draw back to its lowered position, or it may act as a clamp during etching. If the wafer lifter so draws back during dry etching semiconductor processing, it may be subsequently raised to its raised position after semiconductor processing. After processing, the wafer lifter is ultimately lowered to its lowered position (510), so that the wafer may be unloaded therefrom (512), such as by using the wafer chuck.

It is noted that, although specific embodiments have been illustrated and described herein, it will be appreciated by those of ordinary skill in the art that any arrangement is calculated to achieve the same purpose may be substituted for the specific embodiments shown. This application is intended to cover any adaptations or variations of the present invention. Therefore, it is manifestly intended that this invention be limited only by the claims and equivalents thereof.

What is claimed is:

1. A semiconductor dry etching system comprising:
a plasma chamber in which at least polymer is introduced, excess polymer forming and subsequently peeling off inner vertical walls of the chamber and falling down due to gravity; and
a electrically biased mechanism to hold a semiconductor wafer over the plasma chamber, such that the polymer is electrostatically attracted to the wafer, positioning of the wafer over the chamber preventing the excess polymer from falling onto the wafer.

2. The system of claim 1, wherein the electrically biased mechanism comprises a wafer lifter to hold the wafer over the plasma chamber.

3. The system of claim 2, wherein the electrically biased mechanism further comprises a wafer chuck to move the wafer upside-down to over the plasma chamber.

4. The system of claim 3, wherein the electrically biased mechanism further comprises a bias supply to electrically bias at least one of the wafer chuck and the wafer lifter.

5. The system of claim 4, wherein the wafer lifter is vertically movable between a lower position to an upper position, where the lower position promotes loading of the wafer from the wafer chuck, and the upper position enables the bias supply to electrically couple with the wafer chuck for biasing of the wafer.

6. The system of claim 2, wherein the wafer lifter comprises a tubular body having a substantially open-ended cap at a downward-facing end thereof against which the wafer is held.

7. The system of claim 1, further comprising one or more coils to induce a varying magnetic field within the chamber.

8. The system of claim 7, wherein the one or more coils comprise one or more induction coils coupled to an inductive supply.

9. The system of claim 7, wherein the one or more coils comprise one or more electromagnetic coils coupled to an electromagnetic supply.

10. The system of claim 7, further comprising one or more multi-pole magnets cooperating with the one or more coils to assist inducement of the varying magnetic field within the chamber.

11. The system of claim 1, further comprising a dielectric window below the chamber.

12. A semiconductor dry etching system comprising:
a plasma chamber in which at least polymer is introduced;
a wafer lifter to hold a semiconductor wafer upside-down over the plasma chamber; and
a bias supply to bias the wafer chuck and the wafer, such that the polymer is electrostatically attracted to the wafer.

13. The system of claim 12, further comprising a wafer chuck to move the wafer upside-down to over the plasma chamber for the wafer lifter to hold the wafer upside-down over the plasma chamber.

14. The system of claim 12, wherein the wafer lifter comprises a tubular body having a substantially open-ended cap at a downward-facing end thereof against which the wafer is held.

15. The system of claim 12, wherein the wafer lifter is vertically movable between a lower position to an upper position, where the lower position promotes loading of the wafer, and the upper position enables the bias supply to electrically couple with the wafer for biasing thereof.

16. The system of claim 12, further comprising one or more coils to induce a varying magnetic field within the chamber.

17. The system of claim 16, wherein the one or more coils comprise one or more induction coils coupled to an inductive supply.

18. The system of claim 16, further comprising one or more magnets cooperating with the one or more coils to assist inducement of the varying magnetic field within the chamber.

19. The system of claim 12, further comprising a dielectric window below the chamber.

20. A method comprising: lowering a wafer lifter positioned over a plasma chamber of a semiconductor dry etching system;
loading a semiconductor wafer upside-down into the wafer lifter;
raising the wafer lifter to electrically couple the wafer with a cathode of the semiconductor dry etching system; and
performing dry etching semiconductor processing on the wafer.
